(19) United States
(12) Patent Application Publication
(10) Pub. No.: US 2004/0201052 A1
(43) Pub. Date: Oct. 14, 2004

(54) Semiconductor integrated circuit device

(75) Inventor: Yasutaka Nakashiba, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/812,282

(22) Filed: Mar. 30, 2004

(30) Foreign Application Priority Data
Apr. 10, 2003 (JP) 2003-106118

(51) Int. Cl. H01L 31/062

(52) U.S. Cl. 257/296

(57) ABSTRACT

A semiconductor integrated circuit device includes a P type substrate. An N-channel MOS transistor, a P-channel MOS transistor, and an MOS type varactor element are provided in the upper surface of the P type substrate. A gate insulating film of the MOS type varactor element is thinner than gate insulating films of the N-channel MOS transistor and the P-channel MOS transistor. Also, a maximum gate voltage applied between a well terminal and a gate terminal of the MOS type varactor element is lower than a maximum gate voltage applied to the N-channel MOS transistor and the P-channel MOS transistor.

### BACKGROUND OF THE INVENTION

1. Field of the Invention

The present invention relates to a semiconductor integrated circuit (IC) device including an MOS type varactor element.

2. Description of the Related Art

In semiconductor IC devices, MOS (metal oxide semiconductor) type varactor elements have been used as voltage-controlled variable-capacitance elements. An MOS type varactor element is used, for example, for controlling an oscillation frequency of an LC-VCO (voltage-controlled oscillator).

FIGS. 1A to 1C are cross-sectional views showing a conventional semiconductor IC device including an MOS type varactor element. FIG. 1A shows an N-channel MOS transistor, FIG. 1B shows a P-channel MOS transistor, and FIG. 1C shows an MOS type varactor element. These elements shown in FIGS. 1A to 1C are provided in the same semiconductor IC device, and thus they are disposed in the same semiconductor substrate. As shown in FIGS. 1A to 1C, a P type substrate Psub, which is formed of P type silicon for example, is provided in this semiconductor IC device. The N-channel MOS transistor 1, the P-channel MOS transistor 2, and the MOS type varactor element 23 are disposed in the upper surface of the P type substrate Psub.

As shown in FIG. 1A, in the N-channel MOS transistor 1, a P well PW1 is disposed in the-upper surface of the P type substrate Psub. A P type impurity, such as boron (B), is doped into the P well PW1. Further, a gate insulating film 4 is disposed on the P well PW1. The gate insulating film 4 is formed of silicon oxide for example, and the thickness thereof is 8.0 nm. Also, a gate electrode 5, which is formed by patterning polysilicon (polycrystalline silicon) film for example, is disposed on the gate insulating film 4. Further, n⁺ diffusion regions N1 and N2 are placed in two areas in the surface of the P well PW1 sandwiching the gate electrode 5 viewed in the direction vertical to the upper surface of the P type substrate PSub.

Further, a p⁺ diffusion region P1 is placed in the surface of the P well PW1 at an area separated from an area directly under the gate electrode 5 and the n⁺ diffusion regions N1 and N2. Also, a p⁺ diffusion region P2 is placed in the upper surface of the P type substrate PSub in part of an area where the P well PW1 is not disposed. A P type impurity, such as boron (B), is doped into the p⁺ diffusion regions P1 and P2. The n⁺ diffusion region N1 is connected to a source terminal Vs1, the n⁺ diffusion region N2 is connected to a drain terminal Vd1, the gate electrode 5 is connected to a gate terminal Vg1, and the p⁺ diffusion regions P1 and P2 are connected to a ground potential wiring GND.

As shown in FIG. 1B, in the P-channel MOS transistor 2, an N well NW1 is disposed in the upper surface of the P type substrate PSub. An N type impurity, such as phosphorus (P), is doped into the N well NW1. A gate insulating film 4 is disposed on the N well NW1. The gate insulating film 4 is formed at the same time as when the gate insulating film 4 of the N-channel MOS transistor 1 is formed, and thus is formed of silicon oxide and has a thickness of 8.0 nm. Also, a gate electrode 5, which is formed of polysilicon for example, is disposed on the gate insulating film 4. The gate electrode 5 is formed at the same time as when the gate electrode 5 of the N-channel MOS transistor 1 shown in FIG. 1A is formed. Further, p⁺ diffusion regions P3 and P4 are placed in two areas in the upper surface of the N well NW1 sandwiching the gate electrode 5 viewed in the direction vertical to the upper surface of the P type substrate PSub. A P type-impurity, such as boron (B), is-doped into the p⁺ diffusion regions P3 and P4.

Further, an n⁺ diffusion region N3 is placed in the surface of the N well NW1 in an area separated from the area directly under the gate electrode 5 and the p⁺ diffusion regions P3 and P4. Also, a p⁺ diffusion region P5 is placed in the upper surface of the P type substrate PSub in part of an area where the N well NW1 is not disposed. The p⁺ diffusion region P3 is connected to a source terminal Vs2, the p⁺ diffusion region P4 is connected to a drain terminal Vd2, the gate electrode 5 is connected to a gate terminal Vg2, the n⁺ diffusion region N3 is connected to a power-supply potential wiring VDD, and the p⁺ diffusion region P5 is connected to the ground potential wiring GND. The P-channel MOS transistor 2 may form a CMOS transistor together with the N-channel MOS transistor 1.

As shown in FIG. 1C, in the varactor element 23, an N well NW2 is disposed in the upper surface of the P type substrate PSub. The N well NW2 is formed at the same time as when the N well NW1 of the P-channel MOS transistor 2 is formed, and thus the type and concentration of impurity are the same as those in the N well NW1. A gate insulating film 4 is disposed on the N well NW2. The gate insulating film 4 is formed at the same time as when the gate insulating films 4 of the N-channel MOS transistor 1 and the P-channel,MOS transistor 2 are formed, and thus is formed of silicon oxide and has a thickness of 8.0 nm. Also, a gate electrode 5, which is formed of polysilicon for example, is disposed on the gate-insulating film 4.

The gate electrode 5 is formed at the same time as when the gate electrodes 5 of the N-channel MOS transistor 1 shown in FIG. 1A and the P-channel MOS transistor 2 shown in FIG. 1B are formed. Further, n⁺ diffusion regions N4 and N5 are placed in two areas in the surface of the N well NW2 sandwiching the gate electrode 5 viewed in the direction vertical to the upper surface of the P type substrate PSub. The n⁺ diffusion regions N4 and N5 are formed at the same time as when the n⁺ diffusion regions N1 and N2 of the N-channel MOS transistor 1 and the n⁺ diffusion region N3 of the P-channel MOS transistor 2 are formed.

Further, a p⁺ diffusion region P6 is disposed in part of an area where the N well NW2 is not disposed in the upper surface of the P type substrate PSub. The p⁺ diffusion region P6 is formed at the same time as when the p⁺ diffusion regions P1 and P2 of the N-channel MOS transistor 1 and the p⁺ diffusion regions P3 and P4 of the P-channel MOS transistor 2 are formed. The n⁺ diffusion regions N4 and N5 are connected to a well terminal Vb, the gate electrode 5 is connected to a gate terminal Vg3, and the p⁺ diffusion region P6 is connected to the ground-potential wiring GND. In FIGS. 1A to 1C, the gate insulating film 4 is disposed only directly under the gate electrode 5. However, the gate insulating film 4 may be disposed over the entire upper surface of the P type substrate PSub except areas which contacts (not shown) connected to diffusion regions are disposed.

In this conventional semiconductor IC device, a ground potential is applied to the p⁺ diffusion regions P2, P5, and P6 through the ground potential wiring GND, so that the P type substrate PSub is set at the ground potential. Also, a power-supply potential is applied to the n⁺ diffusion region N3 of the P-channel MOS transistor 2 through the power-supply potential wiring VDD, so that the N well NW1 is set at the power-supply potential. By applying a predetermined potential to each of the source terminal Vs1, the drain terminal Vd1, and the gate terminal Vg1 of the N-channel MOS transistor 1, the N-channel MOS transistor 1 is driven. Likewise, by applying a predetermined potential to each of the source terminal Vs2, the drain terminal Vd2, and the gate terminal Vg2 of the P-channel MOS transistor 2, the P-channel MOS transistor 2 is driven.

In the varactor element 23, the capacitance between the gate electrode 5 and the N well NW2 can be changed by changing a voltage applied between the gate terminal Vg3 and the well terminal Vb (hereinafter referred to as gate voltage). That is, by applying a positive potential to the gate terminal Vg3 and a negative potential to the well terminal Vb so as to sufficiently increase the voltage between the terminals, the varactor element 23 is brought into an accumulation state, where the capacitance of the varactor element 23 reaches a maximum, which is substantially equal to the capacitance of the gate insulating film 4. On the other hand, by decreasing the potential applied to the gate terminal Vg3, a depletion layer is generated directly under the gate electrode 5 in the-N well NW2. And, the capacitance of the varactor element 23 decreases with expansion of the depletion layer. By decreasing the potential of the gate terminal Vg3 to a sufficiently low value, the expansion of the depletion layer becomes saturated. Accordingly, the capacitance reaches a minimum and does not decrease any more. Incidentally, the maximum voltage applied between the gate terminal Vg3 and the well terminal Vb is equal to a driving voltage of the N-channel MOS transistor 1 and the P-channel MOS transistor 2, for example, 3.3 V.

As described above, in this semiconductor IC device, the varactor element 23 can be formed in a process of forming the N-channel MOS transistor 1 and the P-channel MOS transistor 2. Therefore, the varactor element 23 can be provided without modifying a process of fabricating the semiconductor IC device or adding a new step.

However, this conventional semiconductor IC device has the following problem. The MOS type varactor element is formed together with the MOSFETs in the same process. Therefore, the characteristic thereof, that is, the range of variable-capacitance and a maximum capacitance per unit area, is determined depending on forming conditions of the MOSFETs. However, the characteristic of the MOS type varactor element should be optimally adjusted in accordance with its use. For example, when the MOS type varactor element is used as a voltage-controlled variable-capacitance element, it is preferable that the range of variable capacitance is as wide as possible, and that the capacitance per unit area is as large as possible.

For example, Japanese Patent Publication Laid Open No. 2002-43842 discloses a technique of providing a voltage-dropping unit and a plurality of varactor elements in a semiconductor IC device, generating a plurality of levels of voltage by the voltage-dropping unit, and applying the voltages to the varactor elements. In this technique, the rate of change in the capacitance can be arbitrarily set.

Alternatively, the concentration of impurity in the N well NW2 may be changed in order to change the characteristic of the MOS type varactor element 23. FIG. 2 is a graph showing a high-frequency C-V characteristic of the MOS type varactor element when the impurity concentration in the N well NW2 (see FIG. 1C) is changed, in which the horizontal axis indicates the voltage between the gate terminal and the well terminal (gate voltage) and the vertical axis indicates the capacitance between the gate terminal and the well terminal. A solid line 21 shown in FIG. 2 is a C-V curve when the impurity concentration of the N well is 1×10¹⁸ cm⁻³. In this case, if the maximum capacitance is Cmax and the minimum capacitance is Cmin, the ratio (Cmax/Cmin) is 5.0. A broken line 22 is a C-V curve when the impurity concentration of the N well is 8×10¹⁷ cm⁻³, and the ratio (Cmax/Cmin) is 5.5. As shown in FIG. 2, when the impurity concentration is reduced from 1×10¹⁸ cm⁻³ to 8×10¹⁷ cm⁻³, the minimum capacitance is reduced and the range of variable capacitance becomes larger by about 1.1 times.

However, those techniques mentioned above have the following problems. In the technique disclosed in Japanese Patent Publication Laid Open No. 2002-43842, although the ratio of change in the capacitance can be controlled, the range of variable capacitance cannot be expanded and the. capacitance per unit area cannot be increased.

Further, in the technique shown in FIG. 2, when the impurity concentration is decreased in order to expand the range of variable capacitance, the maximum capacitance does not increase but the minimum capacitance decreases. Therefore, the capacitance per unit area cannot be increased, although the range of variable capacitance can be expanded. Accordingly, the area of a capacitive element need be increased in order to obtain a desired capacitance. In that case, a dedicated well for a varactor element must be formed, which causes an increase in the layout area.

### SUMMARY OF THE INVENTION

An object of the present invention is to provide a semiconductor integrated circuit device including an MOS type varactor element having a wide range of variable capacitance and a large capacitance per unit area.

A semiconductor integrated circuit device according to the present invention includes: a substrate; MOS transistors which are disposed in the substrate and which include gate insulating films; and an MOS type varactor element which is disposed in the substrate and which includes a gate insulating film, the thickness thereof being thinner than the thinnest gate insulating film among the gate insulating films of the MOS transistors.

In the present invention, by making the gate insulating film of the MOS type varactor element thinner than the gate insulating films of the MOS transistors, a maximum capacitance of the MOS type varactor element can be increased. Accordingly, a capacitance per unit area of the MOS type varactor element can be increased, and the range of variable capacitance of the MOS type varactor element can be expanded.

Preferably, a maximum gate voltage applied to the MOS type varactor element may be lower than a maximum gate voltage applied to the MOS transistors. Accordingly, breakdown of the gate insulating film of the MOS type varactor element caused by an applied voltage can be prevented while maintaining the performance of the MOS transistors.

According to the present invention, since the gate insulating film of the MOS type varactor element is thinner than the gate insulating films of the MOS transistors, a maximum capacitance of the MOS type varactor element can be increased. Accordingly, a capacitance per unit area of the MOS type varactor element can be increased and the range of variable capacitance of the MOS type varactor element can be expanded.

### BRIEF DESCRIPTION OF THE DRAWINGS

FIGS. 1A to 1C are cross-sectional views showing a conventional semiconductor IC device including an MOS type varactor element, in which FIG. 1A shows an N-channel MOS transistor, FIG. 1B shows a P-channel MOS transistor, and FIG. 1C shows an MOS type varactor element;

FIG. 2 is a graph showing a high-frequency C-V characteristic of the MOS type varactor element when the impurity concentration of an N well is changed, in which the horizontal axis indicates a voltage between a gate terminal and a well terminal and the vertical axis indicates a capacitance between the gate terminal and the well terminal;

FIGS. 3A to 3C are cross-sectional views showing a semiconductor IC device according to a first embodiment of the present invention, in which FIG. 3A shows an N-channel MOS transistor, FIG. 3B shows a P-channel MOS transistor, and FIG. 3C shows an MOS type varactor element;

FIG. 4 is a graph showing a high-frequency C-V characteristic of the MOS type varactor element of the first embodiment, in which the horizontal axis indicates a voltage between a gate terminal and a well terminal and the vertical axis indicates a capacitance between the gate terminal and the well terminal; and

FIG. 5 is a cross-sectional view showing an MOS type varactor element of a semiconductor IC device according to a second embodiment of the present invention.

### DETAILED DESCRIPTION OF THE PREFERRED EMBODIMENTS

Hereinafter, embodiments of the present invention will be described with reference to the attached drawings.

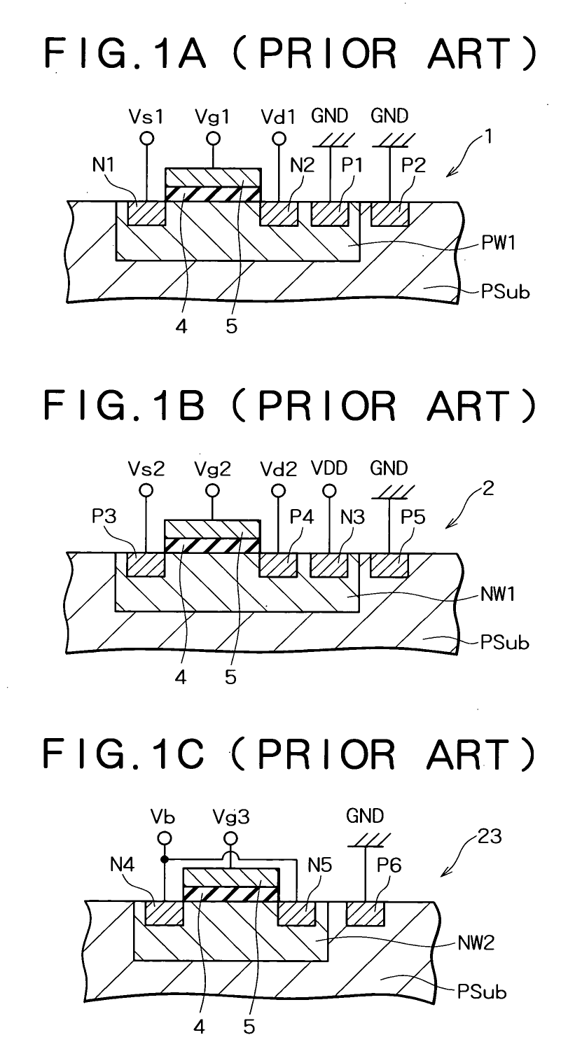

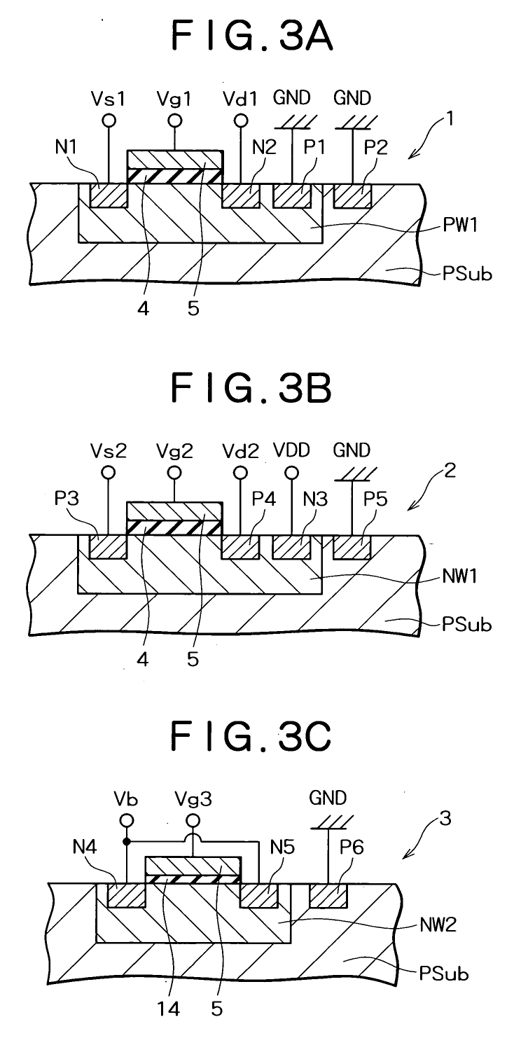

First, a first embodiment of the present invention will be described. FIGS. 3A to 3C are cross-sectional views showing a semiconductor integrated circuit (IC) device according to this embodiment, in which FIG. 3A shows an N-channel MOS transistor, FIG. 3B shows a P-channel MOS transistor, and FIG. 3C shows an MOS type varactor element 3. In this embodiment, elements which are equivalent to those of the conventional semiconductor IC device shown in FIGS. 1A to 1C are denoted by the same reference numerals, and the corresponding description will be omitted. The elements shown in FIGS. 3A to 3C are provided in the same semiconductor IC device, and thus they are provided in the same semiconductor substrate.

As shown in FIGS. 3A to 3C, a P type substrate PSub, which is formed of P type silicon for example, is provided in this semiconductor IC device. The N-channel MOS transistor 1, the P-channel MOS transistor 2, and the MOS type varactor element 3 are provided in the upper surface of the P type substrate PSub. The configuration of the N-channel MOS transistor 1 and the P-channel MOS transistor 2 shown in FIGS. 3A and 3B is the same as that of the N-channel MOS transistor 1 and the P-channel MOS transistor 2 in the conventional semiconductor IC device shown in FIGS. 1A and 1B.

As shown in FIG. 3C, the P type substrate PSub, N well NW2, n⁺ diffusion regions N4 and N5, and p⁺ diffusion region P6 in the varactor element 3 are the same as those in the varactor element 23 in the conventional semiconductor IC device shown in FIG. 1C. That is, the n⁺ diffusion regions N4 and N5 are formed at the same time as when the n⁺ diffusion regions N1 and N2 of the N-channel MOS transistor 1 and the n⁺ diffusion region N3 of the P-channel MOS transistor 2 are formed. Also, the p⁺ diffusion region. P6 is formed at the same time as when the p⁺ diffusion regions P1 and P2 of the N-channel MOS transistor 1 and the p⁺ diffusion regions P3 to P5 of the P-channel MOS transistor 2 are formed.

In the varactor element 3, a gate insulating film 14 is disposed on the N well NW2. The gate insulating film 14 is in the same layer as the gate insulating films 4 of the N-channel MOS transistor 1 and the P-channel MOS transistor 2 shown in FIGS. 3A and 3B, and the gate insulating film 14 is thinner than the gate insulating films 4. For example, the gate insulting film 14 is formed of silicon oxide and has a thickness of 6.0 nm. On the other hand, the gate insulating films 4 of the N-channel MOS transistor 1 and the P-channel MOS transistor 2 have a thickness of 8.0 nm, for example.

The gate electrode 5, which is formed of polysilicon for example, is disposed on the gate insulating film 14. The gate electrode 5 is formed at the same time as when the gate electrodes 5 of the N-channel MOS transistor 1 and the P-channel MOS transistor 2 shown in FIGS. 3A and 3B are formed. The n⁺ diffusion regions N4 and N5 are connected to the well terminal Vb, the gate electrode 5 is connected to the gate terminal Vg3, and the p⁺ diffusion region P6 is connected to the ground potential wiring GND. In FIGS. 3A to 3C, the gate insulating film 4 or 14 is disposed only directly under the gate electrode 5, but the gate insulating film 4 or 14 may be disposed over the entire upper surface of the P type substrate PSub except areas which contacts (not shown) connected to diffusion regions are disposed.

In the semiconductor IC device of this embodiment, each of the gate insulating films 4 and 14 can be formed by a multioxide formation method. For example, a silicon oxide film having a thickness of 3.0 nm is formed on the P type substrate PSub and the silicon oxide film is patterned, so that the silicon oxide film remains only at an area where the gate insulating film 4 is to be formed. Then, a silicon oxide film having a thickness of 6.0 nm is formed and is patterned, so that the silicon oxide film remains only at areas where the gate insulating films 4 and 14 are to be formed. In this way, a silicon oxide film having a thickness of 6.0 nm, which serves as the gate insulating film 14, is formed. Also, the silicon oxide film having a thickness of 3.0 nm, which has been prepared in the previous step, further grows so as to be a silicon oxide film having a thickness of 8.0 nm, which serves as the gate insulating film 4.

Next, the operation of the semiconductor IC device according to this embodiment will be described. The operation of the N-channel MOS transistor 1 and the P-channel MOS transistor 2 of this embodiment is the same as in the conventional semiconductor IC device shown in FIGS. 1A and 1B.

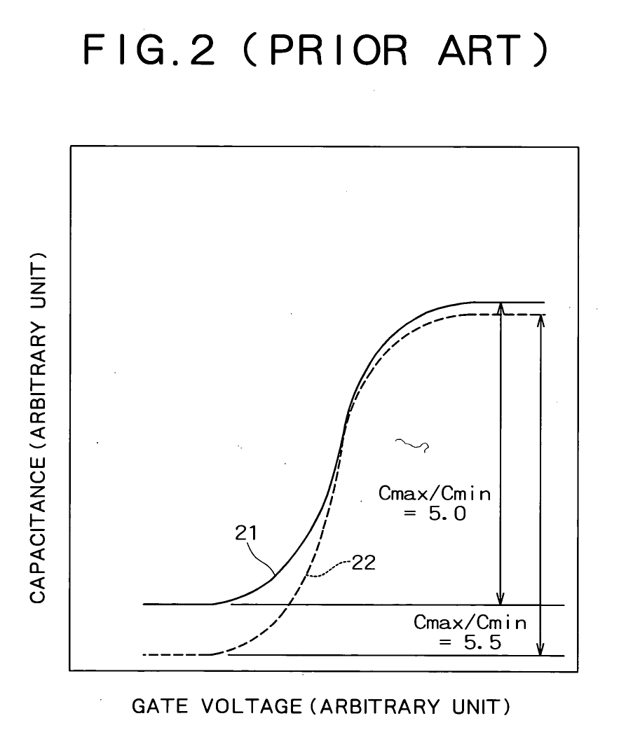

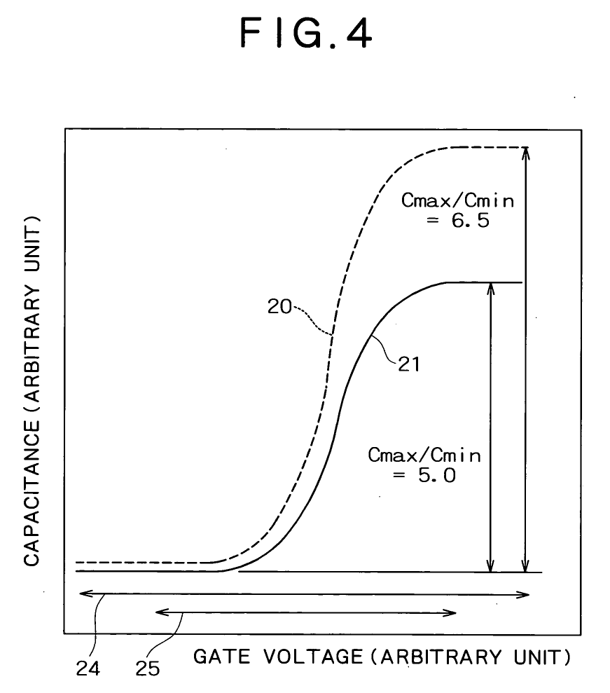

FIG. 4 is a graph showing a high-frequency C-V (capacitance-voltage) characteristic of the MOS type varactor element 3, in which the horizontal axis indicates the voltage between the gate terminal and the well terminal, and the vertical axis indicates the capacitance between the gate terminal and the well terminal. A broken line 20 shown in FIG. 4 indicates a C-V characteristic of the MOS type varactor element 3 of this embodiment, and a solid line 21 indicates a C-V characteristic of the varactor element 23 of the conventional semiconductor IC device, which corresponds to the solid line 21 in FIG. 2.

As shown in FIGS. 3C and 4, in the varactor element 3, the capacitance between the gate electrode 5 and the N well NW2 can be changed by changing the voltage applied between the gate terminal Vg3 and the well terminal Vb (gate voltage). That is, by applying a positive potential to the gate terminal Vg3 and applying a negative potential to the well terminal Vb so as to sufficiently increase the voltage between the two terminals, electrons serving as carriers are accumulated in a channel region, that is, a region directly under the gate electrode 5 in the surface of the N well NW2. Accordingly, the varactor element 3 is brought into an accumulation state, so that the capacitance of the varactor element 3 reaches a maximum, which is substantially equal to the capacitance of the gate insulating film 14. Since the gate insulating film 14 of the MOS type varactor element 3 is thinner than the gate insulating film 4 of the conventional MOS type varactor element 23, the maximum capacitance of the MOS type varactor element 3 is larger than that of the MOS type varactor element 23.

By negatively changing the potential of the gate terminal Vg3 from this state, a depletion layer is generated directly under the gate electrode 5 in the N well NW2, and the capacitance of the varactor element 3 decreases as the depletion layer expands. Further, by decreasing the potential of the gate terminal Vg3 to a sufficiently low value, expansion of the depletion layer becomes saturated. Accordingly, the capacitance of the varactor element 3 reaches a minimum and does not decrease any more. At this time, since the minimum capacitance depends on the thickness of the depletion layer, the minimum capacitance of the MOS type varactor element 3 is substantially equal to that of the MOS type varactor element 23.

At this time, the maximum gate voltage applied to the MOS type varactor element 3 is lower than the gate voltage applied to the N-channel MOS transistor 1 and the P-channel MOS transistor 2. For example, when the range of potential applied to each terminal of the N-channel MOS transistor 1 and the P-channel MOS transistor 2 is 0 (=GND) to 3.3 V (=VDD), the range of potential applied to the gate terminal Vg3 and the well terminal Vb of the MOS type varactor element 3 is 0 to 2.5 V.

In this embodiment, since the gate insulating film 14 of the MOS type varactor element 3 is thinner than the gate insulating films 4 of the N-channel MOS transistor 1 and the P-channel MOS transistor 2, the maximum capacitance of the MOS type varactor element 3 can be increased. Accordingly, when the maximum capacitance is Cmax and the minimum capacitance is Cmin, the ratio (Cmax/Cmin) in the MOS type varactor element 3 is 6.5, as shown by the broken line 20 in FIG. 4. This value is 1.3 times larger than the ratio (Cmax/Cmin) 5.0 in the MOS type varactor element 23 of the conventional semiconductor IC device shown by the solid line 21. In this way, by setting the maximum capacitance of the MOS type varactor element 3 at a high value, the capacitance per unit area can be increased and the range of variable capacitance can be expanded.

When the thickness of the gate insulating film 14 is reduced, the breakdown voltage thereof decreases. In this embodiment, however, the potential applied to the gate terminal Vg3 and the well terminal Vb of the MOS type varactor element 3 is lower than the potential applied to each terminal of the N-channel MOS transistor 1 and the P-channel MOS transistor 2. In this method, breakdown of the gate insulating film 14 can be prevented while maintaining the performance-of the N-channel MOS transistor 1 and the P-channel MOS transistor 2.

ON/OFF control is often performed in the N-channel MOS transistor 1 and the P-channel MOS transistor 2. In this case, the range of gate voltage must be set so that a threshold voltage is stable. The range has a width of 3.3 V, for example. On the other hand, in the MOS type varactor element 3, since the range of gate voltage may be set so that the capacitance significantly changes according to the gate voltage, a stable region in the C-V curve can be minimized. Therefore, even if the range of gate voltage is set at a range 25, which is narrower than a range 24 in the prior art, the range of variable capacitance is not limited.

That is, in the conventional MOS type varactor element 23 (see FIG. 1C), a possible voltage Vgb (=Vg−Vb) between the gate terminal Vg3 and the well terminal Vb is −3.3≦Vgb≦3.3 (V), and the absolute value thereof is |Vgb|≦3.3 (V). On the other hand, in the MOS type varactor element 3 of this embodiment, a possible voltage Vgb is −2.5≦Vgb≦2.5 (V), and the absolute value thereof is |Vgb|≦2.5 (V). Therefore, even if the gate insulating film 14 is thinner than the gate insulating film 4, the gate insulating film 14 is not broken by the voltage. At this time, the width of voltage range 24 shown in FIG. 4 of the prior art is 6.6 V. On the other hand, the width of voltage range 25 of this embodiment is 5.0 V, which is narrower than the voltage range 24. However, as shown in FIG. 4, the voltage range 25 adequately covers a fluctuation range of the C-V curve indicated by the broken line 20, and thus the range of variable capacitance of the varactor element 3 is not limited.

Further, in this embodiment, parts except the gate insulating film 14 of the varactor element 3 can be formed in the process of forming the N-channel MOS transistor 1 and the P-channel MOS transistor 2. Further, as described above, the gate insulating film 14 can be formed by adding an oxidizing step and a patterning step to the process of forming the gate insulating film 4. Therefore, the semiconductor IC device of this embodiment can be fabricated without significantly changing the process of fabricating the conventional semiconductor IC device.

In this embodiment, the thickness of the gate insulating films 4 of the N-channel MOS transistor 1 and the P-channel MOS transistor 2 is set at one level (8.0 nm). However, the present invention is not limited to this, but a plurality of levels may be set, that is, the thickness of the gate insulating films 4 may be different from each other in accordance with a required characteristic for each transistor. In that case, the gate insulating film 14 is made thinner than the thinnest film among the gate insulating films 4.

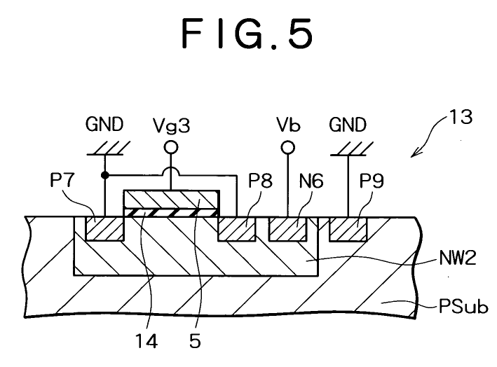

Next, a second embodiment of the present invention will be described. FIG. 5 is a cross-sectional view showing an MOS type varactor element of a semiconductor IC device according to this embodiment. As shown in FIG. 5, the semiconductor IC device of this embodiment includes the N-channel MOS transistor 1 (see FIG. 3A), the P-channel MOS transistor 2 (see FIG. 3B), and the MOS type varactor element 13. The configuration of the N-channel MOS transistor 1 and the P-channel MOS transistor 2 is the same as in the first embodiment.

In the MOS type varactor element 13, the N well NW2 is disposed in the upper surface of the P type substrate PSub, and the gate insulating film 14 is disposed on the N well NW2. The gate insulating film 14 is the same as that in the first embodiment, and includes a silicon oxide film having a thickness of 6.0 nm. The gate electrode 5 is disposed on the gate insulating film 14. Further, p⁺ diffusion regions P7 and P8 are placed in two areas in the surface of the N well NW2 sandwiching the gate electrode 5 viewed in the direction vertical to the upper surface of the P type substrate PSub. A P type impurity, such as boron (B), is doped into the p⁺ diffusion regions P7 and P8.

Further, an n⁺ diffusion region N6 is placed in an area separated from directly under the gate electrode 5 and the p⁺ diffusion regions P7 and P8 in the surface of the N well NW2. Also, a p⁺ diffusion region P9 is placed at a part of an area where the N well NW2 is not disposed in the upper surface of the P type substrate PSub. The gate electrode 5 is connected to the gate terminal Vg3, the n⁺ diffusion region N6 is connected to the well terminal Vb, and the p⁺ diffusion regions P7 to P9 are connected to the ground potential wiring GND.

Next, the operation of the semiconductor IC device of this embodiment will be described. As shown in FIG. 5, in the varactor element 13, a ground potential is applied to the p⁺ diffusion region P9 through the ground potential wiring GND, so that the P type substrate PSub is at the ground potential. Also, by applying a positive potential to the gate terminal Vg3 and applying a negative potential to the well terminal Vb, a capacitance is generated between the N well NW2 and the gate electrode 5. By changing the voltage between the gate terminal Vg3 and the well terminal Vb, the capacitance can be changed. Also, by applying a ground potential to the p⁺ diffusion regions P7 and P8, the p⁺ diffusion regions P7 and P8 absorb positive holes in the N well NW2, so that the capacitance of the varactor element 13 can be stabled. Other than that, the operation and advantages of the varactor element 13 of this embodiment are the same as in the first embodiment.

In the first and second embodiments, the conductive type of the substrate is P type. However, the present invention is not limited to this configuration, but the substrate may be an N type substrate, which is formed of N type silicon for example. In this case, the conductive type of each well and each diffusion region in the surface of the N type substrate is inverted for those shown in FIGS. 3A to 3C and FIG. 5. And, a power-supply potential VDD is applied to n⁺ diffusion regions and a ground potential GND is applied to p⁺ diffusion regions.

What is claimed is:

1. A semiconductor integrated circuit device comprising:
a substrate;
MOS transistors which are disposed in said substrate and which include gate insulating films; and
an MOS type varactor element which is disposed in said substrate and which includes a gate insulating film, the thickness thereof being thinner than the thinnest gate insulating film among said gate insulating films of said MOS transistors.

2. A semiconductor integrated circuit device according to claim 1, wherein a maximum gate voltage applied to said MOS type varactor element is lower than a maximum gate voltage applied to said MOS transistors.

3. A semiconductor integrated circuit device according to claim 1, wherein said substrate is a semiconductor substrate.

4. A semiconductor integrated circuit device according to claim 2, wherein said substrate is a semiconductor substrate.
